(19) United States
(12) Patent Application Publication
(10) Pub. No.: US 2008/0151498 A1
(43) Pub. Date: Jun. 26, 2008

(54) Heat-Radiating Device with a Guide Structure

(76) Inventor: Jie Zhang, Shi Chuan Province (CN)

Correspondence Address: MOLEX INCORPORATED, 2222 WELLINGTON COURT, LISLE, IL, 60532, US

(21) Appl. No.: 11/661,242

(22) PCT Filed: Sep. 6, 2005
(86) PCT No.: PCT/US2005/031602

§ 371 Date: Oct. 1, 2007

(30) Foreign Application Priority Data
Sep. 3, 2004 (CN) 200420093040.7

(51) Int. Cl. H01L 23/467

(52) U.S. Cl. 361/697

(57) ABSTRACT

A heat-radiating device with a guide includes a radiator and a fan. The radiator includes a base and a plurality of radiating fins protruding upward from the top surface of the base. The fan is mounted to one side of the radiator, the air flow from the fan passes through the air gap between two adjacent radiating fins so as to flow out from the side opposite the fan. These radiating fins is protruded bently toward its one side to form a guide structure which inclines from the further side of the base to the closer side of the base in the air flow direction so that the air flow flows downward to the heated electronic elements to radiate heat for them. The guide structure of the present invention is formed integrally with the radiating fins, thus advantages of low cost and easy manufacture are obtained.

### FIELD OF THE INVENTION

The present utility model relates to a heat-radiating device, and in particular, to a heat-radiating device with a guide structure, which is low in cost, is easy in manufacture, and tends to radiate the heat from heated electronic elements around the CPU.

### BACKGROUND OF THE INVENTION

Generally, the current electronic devices, for example, a Central Processing Unit (CPU) in a computer and electronic elements (such as CPU supply module) on mainboards around it, may radiate heat during operation. With increases in processing speed, the heat radiated by the CPU also is increased. Thus, a heat-radiating device is generally attached on the CPU for radiating heat. The heat-radiating device includes a radiator and a fan mounted on one side of the radiator, a plurality of radiating fins are provided in the direction of air flow of the fan, the air flow flows straight toward the radiating fins and does not blow across the electronic elements around the CPU. However, heat produced by these electronic elements, if not dissipated, will exceed their normal operation temperature so that the computer system will be adversely affected. Thereby, a need exists to design a heat-radiating device which can change the flow direction of air flow from the fan to blow across the electronic elements around the CPU so as to help these electronic elements radiate heat.

A conventional guide design is shown as “a heat-radiating device of the CPU” described in China patent No. 01231572.9, the said heat-radiating device is provided with at least one guiding plate in the flow path of air flow formed by the radiating fan, the guiding plate has a curve portion, below the heat-radiating device provides an air flow through-opening opposite to the guiding plate so that the air flow impacts directly on electronic components through the air flow through-opening along the curve portion to radiate heat from the electronic components. However, this guide design needs to mount additionally a guiding plate to the heat-radiating device and needs to fasten the guiding plate to the upper cover of radiating fan by a bolt. This guide design needs additionally a guiding means and a bolt so that the cost of manufacture is higher, and the guiding plate needs a bolt to be fastened so that it will take more time and labor in assembling.

### SUMMARY OF THE INVENTION

A major object of the present invention is to provide a heat-radiating device with a guide structure, which is easy to manufacture, low in cost, and can make the air flow from the fan across the electronic elements around the CPU to help these electronic elements radiate heat.

To achieve the above object, the present invention provides a heat-radiating device with a guide structure, which includes a radiator and a fan, the radiator includes a base and a plurality of radiating fins protruding upward from the top surface of the base, the bottom surface of the base is attached to the top surface of the CPU mounted on a mainboard, these radiating fins are aligned in parallel on the top surface of the base and have two opposite and large-area radiating surfaces, the fan is mounted to one side of the radiator, the air flow generated by the fan passes through the air flow path between opposite radiating surfaces of two adjacent radiating fins so as to flow out from the side opposite to the fan. At least one guide structure protrudes from these radiating surfaces of radiating fins, which inclines from the further side of the base to the closer side of the base in the air flow direction so that the air flow flows downward to the heated electronic elements mounted on the other side of the mainboard opposite to the fan to radiate heat for the electronic elements.

The present invention has the following advantageous effects: the guide structure and the radiating fins are formed integrally so that it is no need to add additionally separate guide element, and to fasten the guide element to the heat-radiating device by a bolt with consumed time and labor, thus advantages of low cost and easy manufacture are obtained.

### BRIEF DESCRIPTION OF DRAWINGS

The features of this invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIG. 1 is a schematic diagram in which the air flow from the heat-radiating device with a guide structure blows the around heated electronic elements according to the utility model;

FIG. 2 is a front view of the heat-radiating device with a guide structure according to the utility model;

FIG. 3 is an isometric view of the heat-radiating device with a guide structure according to the utility model;

FIG. 4 is an isometric view of the radiating fins of the heat-radiating device with a guide structure according to the utility model;

FIG. 5 is an isometric view from another aspect of the heat-radiating device with a guide structure according to the utility model.

### DETAILED DESCRIPTION OF THE DISCLOSED EMBODIMENT

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention.

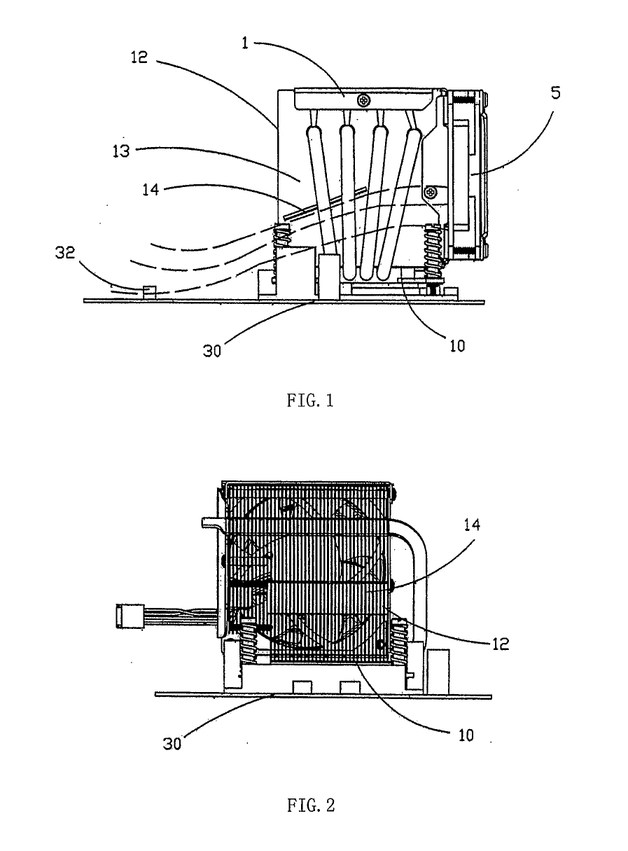

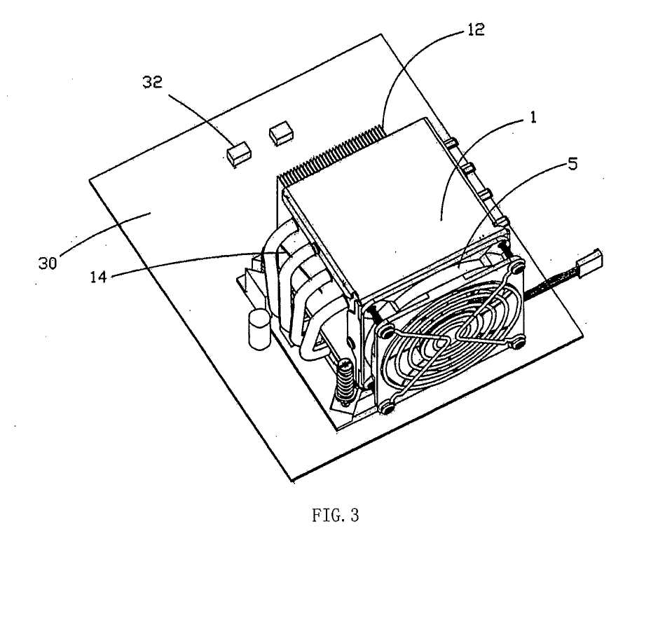

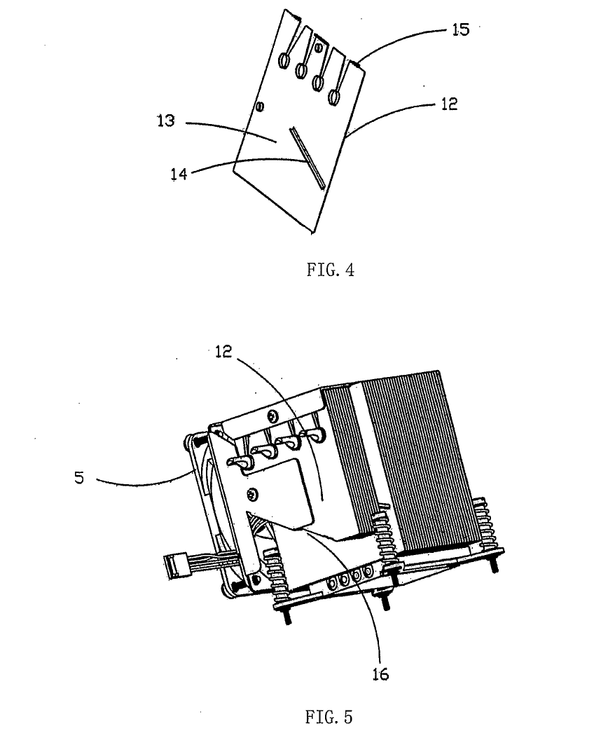

Referring to FIG. 1 to FIG. 5, a heat-radiating device with a guide structure includes a radiator 1 and a fan 5. The radiator 1 is mounted on the top surface of a central processing unit CPU (not shown in Figures) to radiate heat from it, the CPU is mounted on a mainboard 30 which is also provided with a plurality of heated electronic elements 32 on the side opposite to the fan 5.

The radiator 1 includes a base 10 and a plurality of radiating fins 12 protruding upward from the top surface of the base 10. The bottom surface of the base 10 of the radiator 1 is attached tightly to the top surface of the CPU so as to transfer the heat produced by the CPU to the radiating fins 12. These radiating fins 12 are aligned in parallel on the top surface of the base, and have two opposite and large-area radiating surfaces 13. During making these radiating fins 12, a single sheet is formed by cut from a metal strip and punched firstly, then the fastening structures 15 provided on two sides of the radiating fins 12 are fastened together correspondingly, and finally the radiating fins 12 are soldered to the base 10.

The fan 5 is mounted on one side of the radiator 1, the air flow from the fan 5 passes through the air flow path between the opposite radiating surfaces 13 of two adjacent radiating fins 12 so as to flow out from the side of the radiator 1 opposite the fan 5. In this embodiment, in forming by punching the radiating fins 12, in the middle of each radiating surface 13 of the radiating fins 12 punches to form a [ shaped slot, and then the radiating fin 12 in the [ shaped slot is bent vertically to the radiating surface 13 to form a guide sheet 14. The guide sheet 14 inclines from the further side of the base 10 to the closer side of the base 10 in the air flow direction so that the air flow flows downward to the heated electronic elements 32. Though the temperature of air flow passed through the radiator 1 is higher, the temperature of the around heated electronic elements 32 is generally still much higher than the temperature of air flow passed through the radiator 1, thus the air flow can still absorb and take away some heat when blowing these heated electronic elements 32 so as to prevent the heat from accumulating and to ensure that the heated electronic elements 32 operate normally.

The lower of the part radiating fins 12 on one side of the radiator 1 is provided with a cut-out 16 to allow the air flow from the fan 5 to cool the electronic elements (not shown in Figures) below the radiating fins 12.

Illustrated in this embodiment is only one implemented mode of the heat-radiating device with a guide structure according to the present invention, and the guide structure can be not only the guide sheet 14, but also can be a guide rib protruding from the radiating surfaces 13, which is formed by punching on the radiating fins 12 by using malleability of metal. Furthermore, the guide structure illustrated in this embodiment is straight line, but in practice, the guide structure can be designed into a smooth arc line, the same effect can also be obtained.

In the heat-radiating device with a guide structure according to the present invention, the guide structure is formed integrally with the radiating fins 12 when punching to form the radiating fins 12, thereby, it is only to change a little in designing the die for punching the radiating fins 12, and is no need to add an additional separate guide element and to fasten the guide element to the heat-radiating device by a bolt with consumed time and labor, thus advantages of low cost and easy manufacture are obtained.

What is claimed is:

1. A heat-radiating device with a guide structure including a radiator and a fan, wherein the radiator includes a base and a plurality of radiating fins protruding upward from the top surface of the base, the fan is mounted to one side of the radiator, the air flow generated by the fan passes through the air flow path between the radiating fins so as to flow out from the side opposite the fan, characterized in that: in the middle of each of these radiating fins is protruded toward its one side with at least one guide structure which inclines from the further side of the base to the closer side of the base in the air flow direction so that the air flow flows downward to the heated electronic elements to radiate heat from the electronic elements.

2. The heat-radiating device with a guide structure according to claim 1, wherein the radiating fins have two opposite and large-area radiating surfaces.

3. The heat-radiating device with a guide structure according to claim 2, wherein the radiating fins are aligned in parallel on the top surface of the base, and form a air flow path between the opposite radiating surfaces of two adjacent radiating fins.

4. The heat-radiating device with a guide structure according to claim 2, wherein the guide structure is a guide sheet which forms an angle with the radiating surfaces to extend bently from a proper position of the middle of radiating surfaces of the radiating fins.

5. The heat-radiating device with a guide structure according to claim 4, wherein the guide sheet is formed by punching a [ shaped slot in the middle of radiating surfaces of the radiating fins firstly, and then by bending vertically the radiating fins in [ shaped slot to the radiating surface.

6. The heat-radiating device with a guide structure according to claim 2, wherein the guide structure is a guide rib protruding from the middle of radiating surfaces of the radiating fins.

7. The heat-radiating device with a guide structure according to claim 1, wherein the base is attached to the top surface of a CPU mounted on a mainboard, the heated electronic elements are mounted on the other side of the mainboard opposite to the fan.

8. The heat-radiating device with a guide structure according to claim 1, wherein the guide structure is formed into a straight line.

9. The heat-radiating device with a guide structure according to claim 1, wherein the guide structure is formed into a smooth arc line.

10. The heat-radiating device with a guide structure according to claim 1, wherein the lower of the part radiating fins on one side of the radiator is provided with an cut-out to allow the air flow from the fan to cool the electronic elements below the radiating fins.
